(19) United States
(12) Patent Application Publication
(10) Pub. No.: US 2026/0305135 A1
(43) Pub. Date: Oct. 1, 2026

(54) DISPLAY DEVICE AND ELECTRONIC DEVICE COMPRISING THE SAME

(71) Applicant: Samsung Display Co., Ltd., Yongin-si (KR)

(72) Inventors: Taeeun Kim, Yongin-si (KR); Seunghyeon Lee, Yongin-si (KR)

(21) Appl. No.: 19/574,584

(22) Filed: Mar. 23, 2026

(30) Foreign Application Priority Data
Mar. 27, 2025 (KR) 10-2025-0039694

(51) Int. Cl. H10K 59/80; H10K 102/00

(52) U.S. Cl. CPC H10K 59/873; H10K 2102/311

(57) ABSTRACT

A display device includes: a display substrate; a cover panel disposed under the display substrate; a flexible film extending from a front surface of the display substrate and including a first non-bending area, a bending area, and a second non-bending area; a metal layer disposed under the cover panel and having at least a portion disposed apart from the cover panel; and a component disposed under the metal layer.

This application claims priority to Korean Patent Application No. 10-2025-0039694, filed on Mar. 27, 2025, and all the benefits accruing therefrom under 35 U.S.C. §119, the content of which in its entirety is herein incorporated by reference.

### BACKGROUND

### 1. Field

One or more embodiments relate to a display device and an electronic device comprising the same.

### 2. Description of the Related Art

A display device is a device that visually displays data. The display device may provide images using light-emitting diodes. Display devices are becoming more diverse in their uses, and various designs are being attempted to improve the quality of display devices.

### SUMMARY

One or more embodiments include a display device and an electronic device including the same.

Additional aspects will be set forth in part in the description which follows and, in part, will be apparent from the description, or may be learned by practice of the presented embodiments of the disclosure.

According to one or more embodiments, a display device includes a display substrate; a cover panel disposed under the display substrate; a flexible film extending from a front surface of the display substrate and including a first non-bending area, a bending area, and a second non-bending area; a metal layer disposed under the cover panel and having at least a portion disposed apart from the cover panel; and a component disposed under the metal layer.

According to an embodiment, the first non-bending area of the flexible film may be disposed on the front surface of the display substrate.

According to an embodiment, the second non-bending area of the flexible film may be disposed on a rear surface of the display substrate.

According to an embodiment, the bending area of the flexible film may be disposed between the first non-bending area and the second non-bending area.

According to an embodiment, the display device may further include a circuit board disposed between the metal layer and the component.

According to an embodiment, the component may be disposed under the circuit board.

According to an embodiment, the component may be disposed apart from the display substrate.

According to an embodiment, the display device may further include a first adhesive layer disposed between the metal layer and the cover panel.

According to an embodiment, a distance between the first adhesive layer and the metal layer may be from 0.5 millimeters (mm) to 2.0 mm.

According to an embodiment, the display device may further include a driving chip disposed on a front side of the second non-bending area of the flexible film.

According to an embodiment, the display device may further include a spacer disposed on a front surface of the second non-bending area of the flexible film to keep a certain distance between the second non-bending area and the metal layer.

According to an embodiment, the spacer may be provided in plurality, and the driving chip may be disposed between the plurality of spacers.

According an embodiment, the display device may further include an encapsulation layer disposed above top of the display substrate.

According to an embodiment, a display panel may include the display substrate and the encapsulation layer.

According to an embodiment, the display device may further include a second adhesive layer disposed between the metal layer and the circuit board.

According to an embodiment, a portion of the metal layer other than a portion disposed apart from the first adhesive layer may be disposed to be in contact with the first adhesive layer.

According to one or more embodiments, an electronic device includes a display substrate; a cover panel disposed under the display substrate; a flexible film extending from a front surface of the display substrate and including a first non-bending area, a bending area, and a second non-bending area; a metal layer disposed under the cover panel and having at least a portion disposed apart from the cover panel; and a component disposed under the metal layer.

According to an embodiment, the electronic device may further include a circuit board disposed between the metal layer and the component.

According to an embodiment, the electronic device may further include a first adhesive layer disposed between the metal layer and the cover panel.

According to an embodiment, a distance between the first adhesive layer and the metal layer may be from 0.5 mm to 2.0 mm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a perspective view of an electronic device according to an embodiment;

FIG. 1B is an exploded view of an electronic device according to an embodiment;

FIG. 2 is a block diagram of a central processing unit according to an embodiment;

FIG. 3 is a schematic diagrams of electronic devices according to various embodiments;

FIG. 4 is a schematic equivalent circuit diagram of one subpixel circuit provided in a display device according to an embodiment;

FIG. 5 is a schematic cross-sectional view of a display panel according to an embodiment;

FIG. 6 is a schematic side view of a display device according to an embodiment; and

FIG. 7 is a schematic graph of the maximum temperature of a display area of a display substrate according to a distance between a metal layer and a first adhesive layer attached to a lower portion of a cover panel, according to an embodiment.

### DETAILED DESCRIPTION

The disclosure may undergo various modifications and have various embodiments, and specific embodiments are illustrated in the drawings and described in detail in the detailed description. The effects and features of the disclosure and the method for achieving them will become clear with reference to the embodiments described in detail below together with the drawings. However, the disclosure is not limited to the embodiments disclosed below and may be implemented in various forms.

Hereinafter, embodiments of the disclosure will be described in detail with reference to the attached drawings. When describing with reference to the drawings, identical or corresponding components are given the same drawing reference numerals and redundant descriptions thereof are omitted.

In the examples below, the terms “first”, “second”, etc. are not used in a limiting sense but are used for the purpose of distinguishing one component from another.

In the examples below, singular expressions include plural expressions unless the context clearly indicates otherwise.

In the examples below, terms such as "include" or "have" mean that a feature or component described in the specification is present, and do not exclude in advance the possibility that one or more other features or components may be added.

In the following examples, when a part such as a film, region, component, etc. is said to be on or above another part, it includes not only the case where it is directly on top of the other part, but also the case where another film, region, component, etc. is interposed in between.

In the drawings, the sizes of components may be exaggerated or reduced for convenience of explanation. For example, the size and thickness of each component shown in the drawing are arbitrarily shown for convenience of explanation, and thus the disclosure is not necessarily limited to what is shown.

In some embodiments, where the implementation is otherwise feasible, specific process sequences may be performed in a different order than described. For example, two processes described sequentially may be performed substantially simultaneously, or may proceed in the reverse order from that described.

In this specification, “A and/or B” refers to either A, B, or both A and B. And, “at least one of A and B” indicates the case where it is A, or B, or both A and B.

In the following examples, when it is said that a film, region, component, etc. are connected, it includes a case where the films, regions, or components are directly connected, and/or a case where other films, regions, or components are interposed between the films, regions, or components and are indirectly connected. For example, when it is said in this specification that a film, region, component, etc. are electrically connected, it refers to a case where the film, region, component, etc. are directly electrically connected, and/or a case where another film, region, component, etc. is interposed between them and is indirectly electrically connected.

The x-axis, y-axis, and z-axis are not limited to the three axes on the orthogonal coordinate system, and may be interpreted in a broad sense that includes them. For example, the x-axis, y-axis, and z-axis may be orthogonal to each other, but they may also refer to different directions that are not orthogonal to each other.

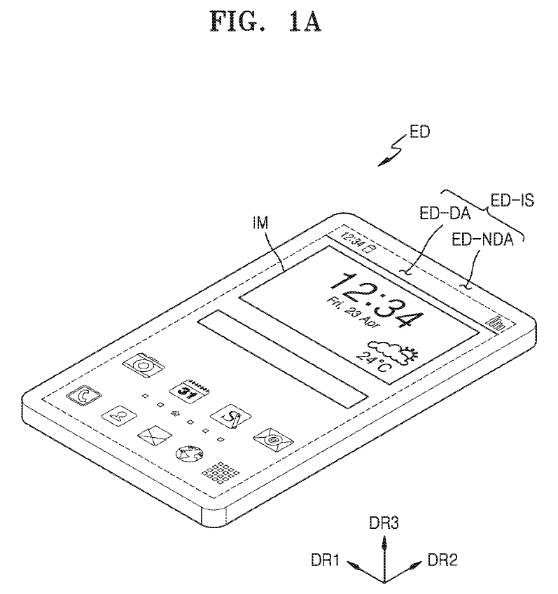

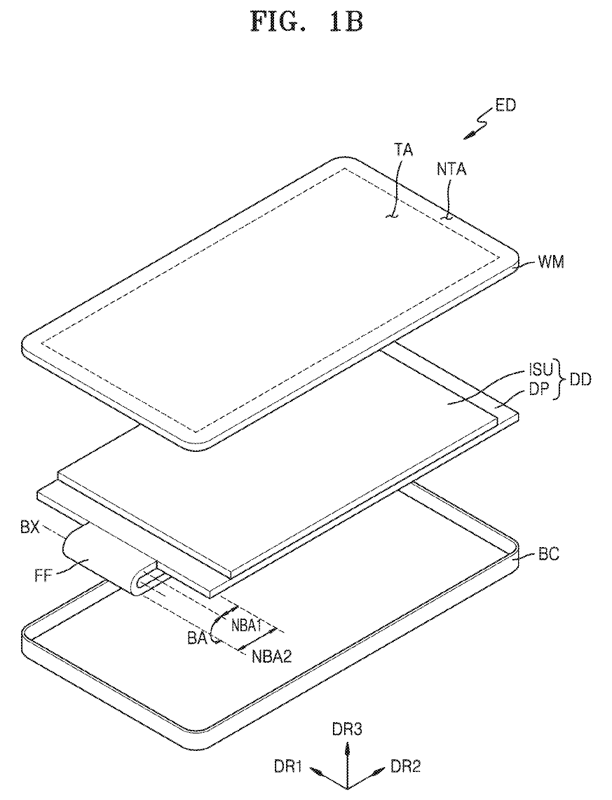

FIG. 1A is a perspective view of an electronic device according to an embodiment. FIG. 1B is an exploded view of an electronic device according to an embodiment.

In this specification, an electronic device of a terminal of a mobile phone is illustrated as an example. An electronic device ED according to an embodiment may be applied to large electronic devices such as televisions, monitors, etc., as well as small and medium-sized electronic devices such as tablets, car navigation systems, game consoles, smart watches, etc.

Referring to FIG. 1A, the electronic device ED may display an image IM through a display surface ED-IS. Icon images are shown as examples of images IM. The display surface ED-IS is parallel to the planes defined by a first direction DR1 and a second direction DR2. The normal direction of the display surface ED-IS, i.e., a thickness direction of the electronic device ED, is indicated by a third direction DR3.

In this specification, the term “when viewed in a plan view or in a plan view” may mean when viewed from the third direction DR3. The front (or top) and back (or bottom) of each layer or unit described below are distinguished by the third direction DR3. However, the combination of the first to third directions DR1, DR2, DR3 may be changed to another combination.

Referring to FIG. 1B, the electronic device ED may include a window WM, a display device DD, and a storage member BC. Although not shown, the electronic device ED may further include an optical element disposed between the window WM and the display device DD. The optical element may include a polarizer.

The window WM is disposed above the display device DD and may transmit images provided from the display device DD to the outside. The window WM contains a transparent area TA and a non-transparent area NTA. The transparent area TA overlaps a display area ED-DA in a plan view and may have a shape corresponding to the display area ED-DA. The window WM may include a base layer and functional layers arranged on the base layer. Functional layers may include a protective layer, an anti-fingerprint layer, etc. The base layer of the window WM may include glass, sapphire, or plastic.

The non-transparent area NTA overlaps the non-display area ED-NDA in a plan view and may have a shape corresponding to a non-display area ED-NDA. The non-transparent area NTA may be an area with relatively low light transmittance compared to the transparent area TA. The non-transparent area NTA may be defined by disposing a bezel pattern in a portion of the base layer of the window WM, and an area where the bezel pattern is not placed may be defined as the transparent area TA. However, the technical idea of the disclosure is not limited thereto, and the non-transparent area NTA may be omitted.

According to an embodiment, a display panel DP may be any one of a liquid crystal display panel, an electrophoretic display panel, a microelectromechanical system display panel, an electrowetting display panel, an organic light emitting display panel, an inorganic light emitting display panel, and a quantum dot light emitting display panel, without particular limitation. Hereinafter, the display panel DP is described as an organic light-emitting display panel.

An input sensor ISU may include any one of a capacitive sensor, an optical sensor, an ultrasonic sensor, and an electromagnetic induction sensor. The input sensor ISU may be formed on the display panel DP through a continuous process, or may be manufactured separately and then attached to the upper side of the display panel DP through an adhesive layer, and is not limited to any embodiment.

According to one embodiment, a flexible film FF extended from the display panel DP may include a first non-bending area NBA1 and a second non-bending area NBA2 disposed apart from each other in the first direction DR1 with a bending area BA interposed therebetween.

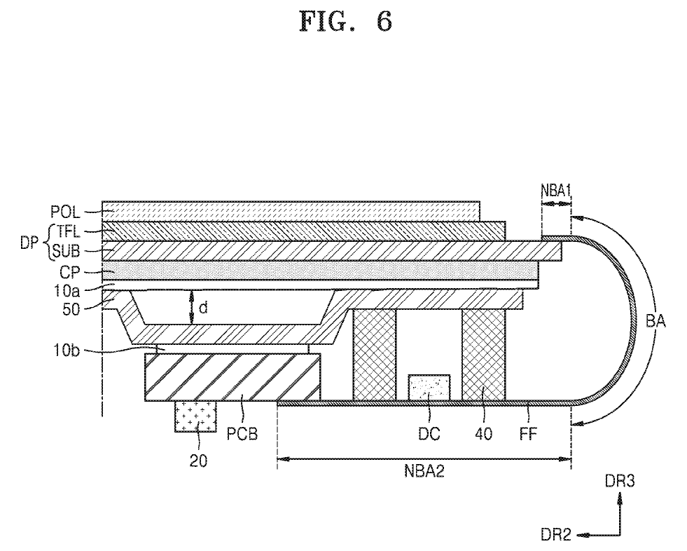

The bending area BA may be defined as an area where the flexible film FF bends along an imaginary bending axis BX extending in the first direction DR1. The first non-bending area NBA1 may be defined as an area overlapping the non-transparent area NTA in a plan view, and the second non-bending area NBA2 may be defined as an area in contact with a circuit board PCB (see FIG. 6).

When the bending area BA is bent based on the bending axis BX, the circuit board PCB and a driving chip DC may be disposed on the back surface of the display panel DP.

Although not shown, additional configurations may be provided to compensate for the step between the back surface of the circuit board PCB and the display panel DP resulting from the bending area BA.

Although an example of the electronic device ED has been described above as a mobile phone terminal, in this specification, the electronic device ED sufficiently includes two or more electrically bonded electronic components. The display panel DP and the driving chip DC mounted on the display panel DP each correspond to different electronic components, and these alone may constitute the electronic device ED and are not limited to any one embodiment.

For example, the electronic device ED may be configured with only the display panel DP and the circuit board PCB connected to the display panel DP, and the electronic device ED may be configured with only a main board and an electronic module mounted on the main board. Hereinafter, the electronic device ED according to an embodiment will be described with a focus on the bonding structure of the display panel DP and the driving chip DC mounted on the display panel DP.

The display device according to an embodiment may be applied to various electronic devices. The electronic device according to one embodiment includes the display device described above, and may further include a module or device having additional functions in addition to the display device.

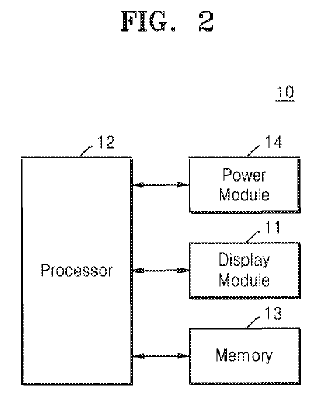

FIG. 2 is a block diagram of a central processing unit according to an embodiment. Referring to FIG. 2, an electronic device 10 according to one embodiment may include a display module 11, a processor 12, a memory 13, and a power module 14.

The processor 12 may include at least one of a central processing unit CPU, an application processor AP, a graphic processing unit GPU, a communication processor CP, an image signal processor ISP, and a controller.

Data information necessary for the operation of the processor 12 or the display module 11 may be stored in the memory 15. When the processor 12 executes an application stored in the memory 15, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the above-described electronic device may be included in a display device according to the above-described embodiments. Additionally, some of the individual modules functionally included within a module may be included within the display device, while others may be provided separately from the display device. For example, the display device may include the display module 11, and the processor 12, the memory 13 and the power module 14 may be provided in the form of other devices within the electronic device other than the display device.

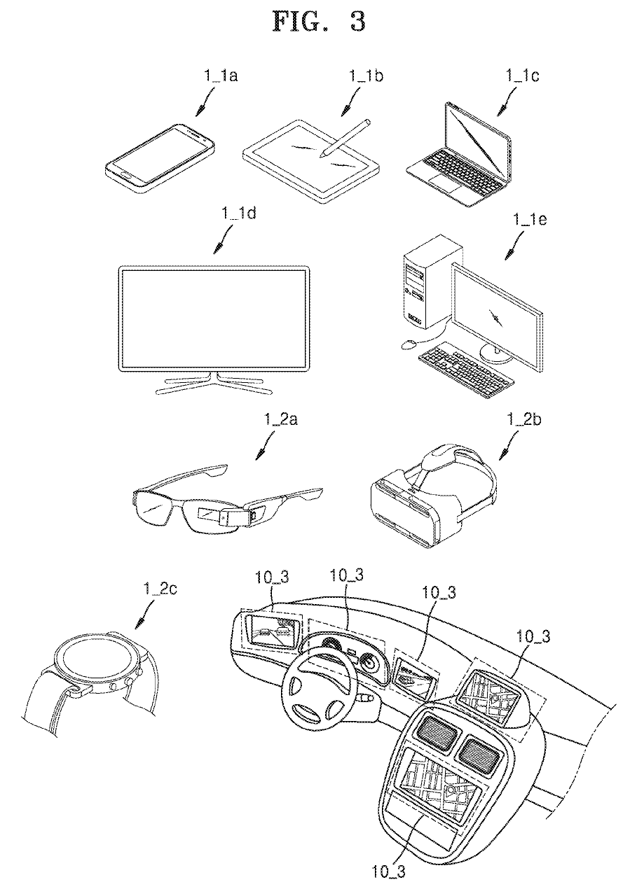

FIG. 3 is a schematic diagram of an electronic device according to various embodiments.

Referring to FIG. 3, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and car instrument panel.

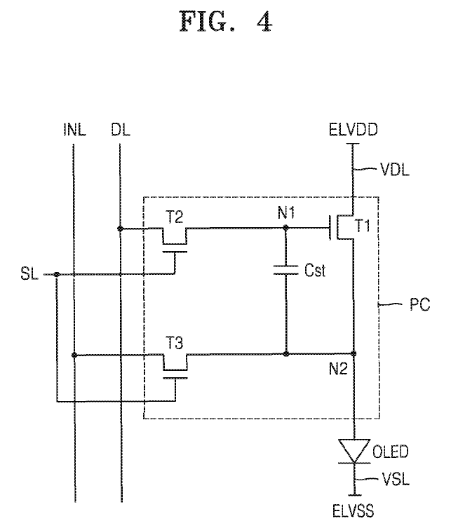

FIG. 4 schematically illustrates an equivalent circuit diagram of one subpixel circuit provided in another display device according to one embodiment.

Referring to FIG. 4, a subpixel circuit PC may include a plurality of thin film transistors and at least one capacitor. In one embodiment, the subpixel circuit PC may include a first thin film transistor T1, a second thin film transistor T2, a third thin film transistor T3, and a storage capacitor Cst.

Each of the first thin film transistor T1, the second thin film transistor T2, and the third thin film transistor T3 may be an oxide semiconductor thin film transistor including a semiconductor layer composed of an oxide semiconductor, or a silicon semiconductor thin film transistor including a semiconductor layer composed of polysilicon. Each thin film transistor has a first electrode and a second electrode and depending on the type of the thin film transistor, the first electrode may be one of a source electrode and a drain electrode, and the second electrode may be the other of the source electrode and the drain electrode. Additionally, each thin film transistor may have a gate electrode.

The first thin film transistor T1 may be a driving thin film transistor. A first electrode of the first thin film transistor T1 may be connected to a driving voltage line VDL that supplies a driving power voltage ELVDD, and a second electrode may be connected to a pixel electrode of an organic light-emitting diode OLED. A gate electrode of the first thin film transistor T1 may be connected to a first node N1. The first thin film transistor T1 may control the amount of current flowing through the organic light emitting diode OLED from the driving power voltage ELVDD in response to the voltage of the first node N1.

The second thin film transistor T2 may be a switching thin film transistor. A first electrode of the second thin film transistor T2 may be connected to a data line DL, and a second electrode may be connected to a first node N1. A gate electrode of the second thin film transistor T2 may be connected to a scan line SL. The second thin film transistor T2 may be turned on when a scan signal is supplied to the scan line SL to electrically connect the data line DL and the first node N1.

The third thin film transistor T3 may be an initialization thin film transistor and/or a sensing thin film transistor. A first electrode of the third thin film transistor T3 may be connected to a second node N2, and a second electrode may be connected to an initialization voltage line INL. A gate electrode of the third thin film transistor T3 may be connected to the scan line SL.

The third thin film transistor T3 may be turned on when a scan signal is supplied to the scan line SL to electrically connect the initialization voltage line INL and the second node N2. In some embodiments, the third thin film transistor T3 may be turned on according to a signal received through the scan line SL to initialize a pixel electrode of the organic light emitting diode OLED with an initialization voltage from the initialization voltage line INL.

In some embodiments, the third thin film transistor T3 may be turned on when a scan signal is supplied to the scan line SL to sense characteristic information of the organic light emitting diode OLED. The third thin film transistor T3 may have both the function of the aforementioned initialization thin film transistor and the function of the sensing thin film transistor, or may have only one of the functions. The initialization operation and sensing operation of the third thin film transistor T3 may be performed separately or simultaneously. When the third thin film transistor T3 functions as a sensing thin film transistor, the initialization voltage line INL may be named a sensing line.

The storage capacitor Cst may be connected between the first node N1 and the second node N2. For example, a first capacitor plate of the storage capacitor Cst may be connected to the gate electrode of the first thin film transistor T1, and a second capacitor plate of the storage capacitor Cst may be connected to the pixel electrode of the organic light-emitting diode OLED.

A counter electrode of the organic light-emitting diode OLED may be connected to a common voltage line VSL that provides a common power supply voltage ELVSS.

Although FIG. 4 illustrates that the subpixel circuit PC includes three thin film transistors and one storage capacitor, the disclosure is not limited thereto. In other embodiments, the number of thin film transistors or the number of storage capacitors may vary depending on the design of the subpixel circuit PC.

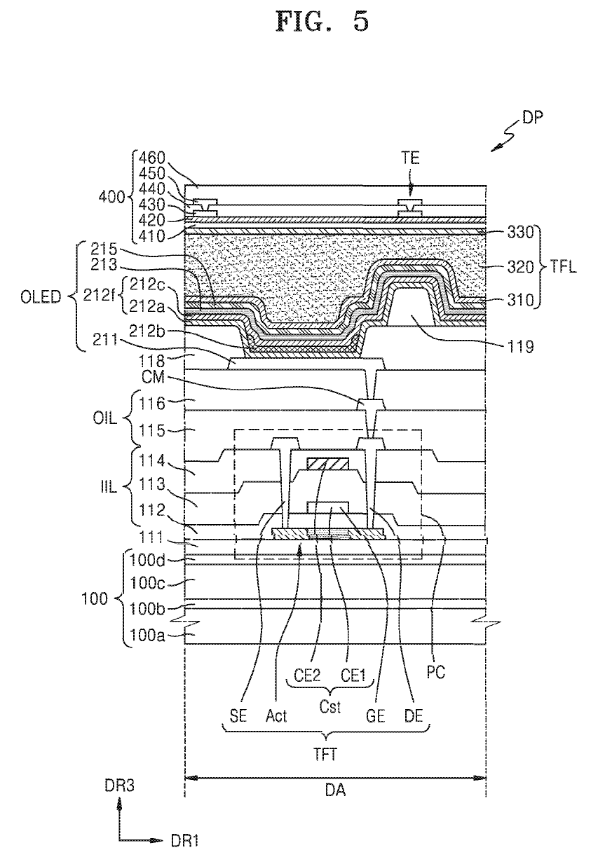

FIG. 5 schematically illustrates a cross-sectional view of a display panel according to an embodiment.

Referring to FIG. 5, a base substrate 100 may include a first base layer 100a, a first barrier layer 100b, a second base layer 100c, and a second barrier layer 100d. In one embodiment, the first base layer 100a, the first barrier layer 100b, the second base layer 100c, and the second barrier layer 100d may be sequentially laminated in the thickness direction of the base substrate 100.

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 100b and the second barrier layer 100dare barrier layers that prevent the penetration of external foreign substances, and may be a single layer or multiple layers including inorganic materials such as silicon nitride (SiN_{X}), silicon oxide (SiO₂), and/or silicon oxynitride (SiON).

A buffer layer 111 may be disposed on the base substrate 100. The buffer layer 111 may include an inorganic insulator such as silicon nitride (SiN_{X}), silicon oxynitride (SiON), and silicon oxide (SiO₂), and may be a single layer or multilayer including the aforementioned inorganic insulator.

An inorganic insulating layer IIL may be disposed on the buffer layer 111. The inorganic insulating layer IIL may include a first gate insulating layer 112, a second gate insulating layer 113, and an interlayer insulating layer 114.

A subpixel circuit PC may be arranged in a display area DA. The subpixel circuit PC may include a thin film transistor TFT and a storage capacitor Cst. The thin film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. Alternatively, the semiconductor layer Act may include amorphous silicon, an oxide semiconductor, an organic semiconductor, etc. The semiconductor layer Act may include a channel area and a drain area and a source area disposed on both sides of the channel area, respectively.

A gate electrode GE may be disposed on the semiconductor layer Act. The gate electrode GE may overlap the channel area. The gate electrode GE may include a low-resistance metal material. The gate electrode GE may include a conductive material including molybdenum (Mo), aluminum (Al), copper (Cu), titanium (Ti), etc., and may be formed as a multilayer or single layer including the above-mentioned materials.

The first gate insulating layer 112 may be disposed between the semiconductor layer Act and the gate electrode GE. The first gate insulating layer 112 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second gate insulating layer 113 may be disposed on the gate electrode GE. The second gate insulating layer 113 may be provided to cover the gate electrode GE. The second gate insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second capacitor plate CE2 of the storage capacitor Cst may be disposed on the second gate insulating layer 113. The second capacitor plate CE2 may overlap with the gate electrode GE disposed underneath it. At this time, the gate electrode GE and the second capacitor plate CE2 overlapping with the second gate insulating layer 113 in between may form the storage capacitor Cst in a plan view. That is, the gate electrode GE may function as the first capacitor plate CE1 of the storage capacitor Cst.

In this way, the storage capacitor Cst and the thin film transistor TFT may be formed by overlapping each other in a plan view. However, the disclosure is not limited thereto. For example, the storage capacitor Cst may be formed so as not to overlap with the thin film transistor TFT in a plan view. That is, the first capacitor plate CE1 of the storage capacitor Cst may be provided as a separate component from the gate electrode GE of the thin film transistor TFT and disposed apart from the gate electrode GE of the thin film transistor TFT.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the aforementioned materials.

The interlayer insulating layer 114 may be disposed on the second capacitor plate CE2. The interlayer insulating layer 114 may cover the second capacitor plate CE2. The interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 114 may be a single layer or multiple layers including the aforementioned inorganic insulating material.

A drain electrode DE and a source electrode SE may each be disposed on the interlayer insulating layer 114. The drain electrode DE and the source electrode SE may be connected to the semiconductor layer Act through contact holes provided in the first gate insulating layer 112, the second gate insulating layer 113, and the interlayer insulating layer 114, respectively. The drain electrode DE and source electrode SE may include a material having good conductivity. The drain electrode DE and the source electrode SE may include a conductive material including molybdenum (Mo), aluminum (Al), copper (Cu), titanium (Ti), etc., and may be formed as a multilayer or single layer including the aforementioned materials. For example, the drain electrode DE and the source electrode SE may have a multilayer structure of Ti/Al/Ti.

An organic insulating layer OIL may be disposed on the inorganic insulating layer IIL. The organic insulating layer OIL may include a first organic insulating layer 115 and a second organic insulating layer 116. Although FIG. 6 illustrates that the organic insulating layer OIL has two layers, the disclosure is not limited thereto. The organic insulating layers OIL may be provided in three or four layers.

The first organic insulating layer 115 may cover the drain electrode DE and the source electrode SE. The first organic insulating layer 115 may include an organic insulating material such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

A connection electrode CM may be disposed on the first organic insulating layer 115. At this time, the connection electrode CM may be connected to the drain electrode DE or the source electrode SE through the contact hole of the first organic insulating layer 115. The connection electrode CM may include a material having good conductivity. The connection electrode CM may include a conductive material including molybdenum (Mo), aluminum (Al), copper (Cu), titanium (Ti), etc., and may be formed as a multilayer or single layer including the aforementioned materials. For example, the connection electrode CM may have a multilayer structure of Ti/Al/Ti.

The second organic insulating layer 116 may be placed on the connection electrode CM. The second organic insulating layer 116 may cover the connection electrode CM. The second organic insulating layer 116 may be formed of the same material as the first organic insulating layer 115 or may be formed of a different material.

A light-emitting diode may be placed on the second organic insulating layer 116. For example, an organic light-emitting diode OLED may be placed on the second organic insulating layer 116. Alternatively, although not shown, an inorganic light-emitting diode or the like may be disposed on the second organic insulating layer 116.

The organic light-emitting diodes OLED may emit red, green, or blue light, or they can emit red, green, blue, or white light. The organic light-emitting diode OLED may include a first electrode 211, a light-emitting layer 212b, a functional layer 212f, a second electrode 213, and a capping layer 215. The first electrode 211 may be a pixel electrode (e.g., an anode) of the organic light-emitting diode OLED, and the second electrode 213 may be a counter electrode (e.g., a cathode) of the organic light-emitting diode OLED.

The first electrode 211 may be disposed on the second organic insulating layer 116. The first electrode 211 may be electrically connected to the connection electrode CM through a contact hole defined in the second organic insulating layer 116. The first electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In one embodiment, the first electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In one embodiment, the first electrode 211 may further include a film formed of ITO, IZO, ZnO or In₂O₃ above/below the aforementioned reflective film. For example, the first electrode 211 may have a multilayer structure of ITO/Ag/ITO.

A pixel definition layer 118 having an opening defined to expose at least a portion of the first electrode 211 may be disposed on the first electrode 211. The light emission area of light emitted from the organic light-emitting diode OLED may be defined by the opening defined in the pixel definition layer 118. For example, the width of the opening may correspond to the width of the emitting area.

The pixel definition layer 118 may include an organic insulating material. Alternatively, the pixel definition layer 118 may include an inorganic insulating material such as silicon nitride, silicon oxynitride, or silicon oxide. Alternatively, the pixel definition layer 118 may include an organic insulating material and an inorganic insulating material. In one embodiment, the pixel definition layer 118 may include a light-blocking material. The light-blocking material may include a resin or paste containing carbon black, carbon nanotubes, black dye, metal particles such as nickel, aluminum, molybdenum, and alloys thereof, metal oxide particles (e.g., chromium oxide) or metal nitride particles (e.g., chromium nitride), etc. When the pixel definition layer 118 includes a light-blocking material, external light reflection by metal structures arranged under the pixel definition layer 118 may be reduced.

A spacer 119 may be disposed on the pixel definition layer 118. The spacer 119 may include an organic insulating material such as polyimide. Alternatively, the spacer 119 may include an inorganic insulator such as silicon nitride (SiN_{X}) or silicon oxide (SiO₂), or may include an organic insulator and an inorganic insulator.

In one embodiment, the spacer 119 may comprise the same material as the pixel definition layer 118. In this case, the pixel definition layer 118 and the spacer 119 may be formed together in a mask process using a half-tone mask, etc. Alternatively, the spacer 119 and the pixel definition layer 118 may contain different materials.

The light-emitting layer 212b may be disposed in the opening of the pixel definition layer 118. The light-emitting layer 212b may include a polymer or low-molecular organic material that emits light of a predetermined color.

The functional layer 212f may include a first functional layer 212a and a second functional layer 212c. The first functional layer 212a may be disposed between the first electrode 211 and the light-emitting layer 212b, and the second functional layer 212c may be disposed between the light-emitting layer 212band the second electrode 213. However, at least one of the first functional layer 212a or the second functional layer 212c may be omitted. Below, a detailed description will be given focusing on the case where the first functional layer 212a and the second functional layer 212c are respectively disposed.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be a common layer formed to cover the entire base substrate 100, similar to the second electrode 213 described later.

The second electrode 213 may be disposed on the functional layer 212f. The second electrode 213 may be made of a conductive material having a low work function. For example, the second electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 213 may further include a layer such as ITO, IZO, ZnO or In 2O3 on the (semi)transparent layer including the aforementioned material.

In one embodiment, the capping layer 215 may be disposed on the second electrode 213. The capping layer 215 may include LiF, an inorganic material, or/and an organic material.

An encapsulation layer TFL may be disposed on the organic light-emitting diode OLED. The encapsulation layer TFL may cover the organic light-emitting diode OLED. The encapsulation layer TFL may be disposed on the second electrode 213 and/or the capping layer 215. In one embodiment, the encapsulation layer TFL may include at least one inorganic encapsulating layer and at least one organic encapsulating layer. FIG. 3 illustrates that the encapsulation layer TFL includes a first inorganic encapsulation layer 310, an organic encapsulation layer 320, and a second inorganic encapsulation layer 330 that are sequentially laminated.

The first inorganic encapsulation layer 310 and the second inorganic encapsulation layer 330 may include one or more inorganic materials selected from aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multiple layers containing the materials described above. The organic encapsulation layer 320 may include a polymer-based material. Polymer-based materials may include acrylic resins, epoxy resins, polyimides, and polyethylene. In one embodiment, the organic encapsulation layer 320 may include acrylate.

An input sensing layer 400 may be disposed on the encapsulation layer TFL. The input sensing layer 400 may include a first touch insulating layer 410, a second touch insulating layer 420, a first conductive layer 430, a third touch insulating layer 440, a second conductive layer 450, and a planarization layer 460.

In one embodiment, a first touch insulating layer 410 may be disposed on a second inorganic encapsulation layer 330, and a second touch insulating layer 420 may be disposed on the first touch insulating layer 410. In one embodiment, the first touch insulating layer 410 and the second touch insulating layer 420 may include an inorganic insulating material and/or an organic insulating material. For example, the first touch insulating layer 410 and the second touch insulating layer 420 may include an inorganic insulating material such as silicon oxide, silicon nitride, and/or silicon oxynitride.

In one embodiment, at least one of the first touch insulating layer 410 and the second touch insulating layer 420 may be omitted. For example, the first touch insulating layer 410 may be omitted. In this case, the second touch insulating layer 420 may be placed on the second inorganic encapsulation layer 330, and the first conductive layer 430 may be disposed on the second touch insulating layer 420.

The first conductive layer 430 may be placed on the second touch insulating layer 420, and the third touch insulating layer 440 may be disposed on the first conductive layer 430. In one embodiment, the third touch insulating layer 440 may include an inorganic insulating material and/or an organic insulating material. For example, the third touch insulating layer 440 may include an inorganic insulating material such as silicon oxide, silicon nitride, and/or silicon oxynitride.

The second conductive layer 450 may be disposed on the third touch insulating layer 440. A touch electrode TE of the input sensing layer 400 may be provided with a structure in which the first conductive layer 430 and the second conductive layer 450 are connected. Alternatively, the touch electrode TE may be formed on either the first conductive layer 430 or the second conductive layer 450 and may include a metal line provided in the corresponding conductive layer. The first conductive layer 430 and the second conductive layer 450 may each include at least one of aluminum (Al), copper (Cu), titanium (Ti), molybdenum (Mo), and indium tin oxide (ITO), and may be formed as a single layer or multiple layers including the aforementioned materials. For example, the first conductive layer 430 and the second conductive layer 450 may each have a three-layer structure of titanium layer/aluminum layer/titanium layer.

In one embodiment, the planarization layer 460 may cover the second conductive layer 450. The planarization layer 460 may include an organic insulating material.

FIG. 6 is a schematic side view of a display device according to an embodiment.

Referring to FIG. 6, a cover panel CP may be disposed under a display panel DP. The display panel DP may include a display substrate SUB and an encapsulation layer TFL disposed thereon. In other words, the cover panel CP may be disposed on the lower part of the display substrate SUB of the display panel DP.

A flexible film FF may extend from the front surface of the display substrate SUB. In other words, at least a portion of a flexible film FF may be in contact with at least a portion of the front surface of the display substrate SUB. The flexible film FF may include a first non-bending area NBA1, a bending area BA, and a second non-bending area NBA2. The bending area BA may be disposed between the first non-bending area NBA1 and the second non-bending area NBA2. The first non-bending area NBA1 of the flexible film FF may be disposed on the front surface of the display substrate SUB. The second non-bending area NBA2 of the flexible film FF may be disposed on the back surface of the display substrate SUB. As used herein, the “front surface” of a layer is an upper surface of the layer facing the third direction DR3, and a “rear surface” of the layer is a lower surface of the layer facing a direction opposite to the third direction DR3.

A metal layer 50 may be disposed on the lower part of the cover panel CP. A first adhesive layer 10a may be disposed between the metal layer 50 and the cover panel CP. At least a portion of the metal layer 50 may be disposed apart from the cover panel CP. In other words, a space may be disposed between the metal layer 50 and the cover panel CP. The distance between the metal layer 50 and the first adhesive layer 10a attached to the lower part of the cover panel CP may be 0.5 millimeters (mm) to 2.0 mm.

A circuit board PCB may be disposed underneath the metal layer 50. A second adhesive layer 10b may be disposed between the circuit board PCB and the metal layer 50. A circuit board PCB may be disposed on the front surface of the second non-bending area NBA2 of the flexible film FF. Specifically, the circuit board PCB may be disposed between a metal layer 50 and the second non-bending area NBA2 of the flexible film FF. A driving chip DC may be disposed on the front side of the second non-bending area NBA2 of the flexible film FF.

A spacer 40 may be disposed on the front surface of the non-bending area NBA2 of the flexible film FF. The spacer 40 may be disposed on the front surface of the second non-bending area NBA2 of the flexible film FF with the driving chip DC interposed therebetween.

A component 20 may be disposed on the back surface of the circuit board PCB. The component 20 may be disposed to overlap with the display substrate SUB in a plan view. The component 20 may be a highly exothermic component.

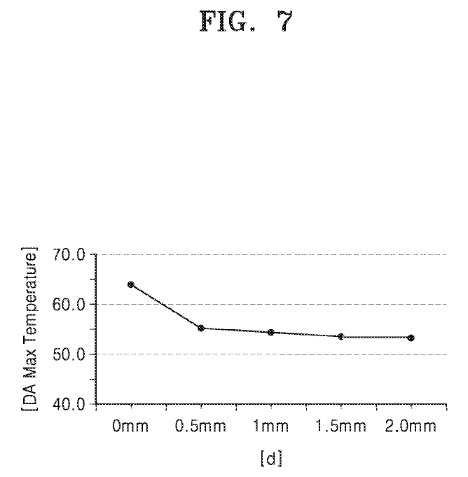

FIG. 7 is a schematic diagram illustrating a graph of the maximum temperature of a display area of a display substrate according to the distance between a metal layer and a first adhesive layer attached to a lower portion of a cover panel according to an embodiment.

Referring to FIG. 7, in one embodiment, the distance d between a metal layer 50 (see, FIG. 6) and the first adhesive layer 10a (see, FIG. 6) attached to the lower portion of the cover panel CP (see, FIG. 6) may be 0.5 mm to 2.0 mm. When the distance d between the first adhesive layer 10a and the metal layer 50 is 0 mm, heat emitted from the component 20 (see, FIG. 6) disposed on the lower portion of the metal layer 50 is transferred to the display substrate SUB (see, FIG. 6), so that the maximum temperature of a display area of the display substrate SUB may be approximately 64°C. In contrast, when the distance d between the metal layer 50 and the first adhesive layer 10a attached to the lower portion of the cover panel CP is 0.5 mm or more, the degree to which heat emitted from the component 20 disposed on the lower portion of the metal layer 50 is transferred to the display substrate SUB is reduced, so that the maximum temperature of the display area of the display substrate SUB may be about 55°C or less. However, if the distance d between the metal layer 50 and the first adhesive layer 10a attached to the lower part of the cover panel CP exceeds 2.0 mm, the thickness of the display device may increase, thereby reducing the convenience and reliability of the display device. As shown in FIG. 6, a distance between the metal layer 50 and the first adhesive layer 10a in the third direction DR3 may vary depending on a measuring point. The component 20 may overlap a first portion of the metal layer 50 in a plan view in which a distance to the first adhesive layer 10a is the distance d, a second portion of the metal layer 50 may be in contact with the first adhesive layer 10a, and in a third portion of the metal layer 50 between the first portion and the second portion, the distance between the metal layer 50 and the first adhesive layer 10a may increase from 0 mm to the distance d in a direction from the second portion to the first portion.

According to one embodiment as described above, the display device with improved reliability and quality and the electronic device including the same may be implemented. However, the scope of the disclosure is not limited by these effects.

Although the disclosure has been described with reference to the embodiments shown in the drawings, these are merely exemplary, and those skilled in the art will understand that various modifications and equivalent other embodiments are possible therefrom. Therefore, the true technical protection scope of the disclosure should be determined by the technical idea of the attached patent claims.

What is claimed is:

1. A display device comprising:
a display substrate;
a cover panel disposed under the display substrate;
a flexible film extending from a front surface of the display substrate and including a first non-bending area, a bending area, and a second non-bending area;
a metal layer disposed under the cover panel and having at least a portion disposed apart from the cover panel; and
a component disposed under the metal layer.

2. The display device of claim 1,
wherein the first non-bending area of the flexible film is disposed on the front surface of the display substrate.

3. The display device of claim 1,
wherein the second non-bending area of the flexible film is disposed on a rear surface of the display substrate.

4. The display device of claim 1,
wherein the bending area of the flexible film is disposed between the first non-bending area and the second non-bending area.

5. The display device of claim 1,
further comprising a circuit board disposed between the metal layer and the component.

6. The display device of claim 5,
wherein the component is disposed under the circuit board.

7. The display device of claim 1,
wherein the component is disposed apart from the display substrate.

8. The display device of claim 1,
further comprising a first adhesive layer disposed between the metal layer and the cover panel.

9. The display device of claim 8,
wherein a distance between the first adhesive layer and the metal layer is 0.5 millimeters (mm) to 2.0 mm.

10. The display device of claim 1,
further comprising a driving chip disposed on a front surface of the second non-bending area of the flexible film.

11. The display device of claim 1,
further comprising a spacer disposed on a front surface of the second non-bending area of the flexible film to keep a certain distance between the second non-bending area and the metal layer.

12. The display device of claim 11,
wherein the spacer is disposed with the driving chip therebetween.

13. The display device of claim 1,
further including an encapsulation layer disposed above the display substrate.

14. The display device of claim 13, further comprising
a display panel, which includes the display substrate and the encapsulation layer.

15. The display device of claim 5,
further comprising a second adhesive layer disposed between the metal layer and the circuit board.

16. The display device of claim 8,
wherein a portion of the metal layer other than a portion disposed apart from the first adhesive layer may be disposed to be in contact with the first adhesive layer.

17. An electronic device comprising:
a display substrate;
a cover panel disposed under the display substrate;
a flexible film extending from a front surface of the display substrate and including a first non-bending area, a bending area, and a second non-bending area;
a metal layer disposed under the cover panel and having at least a portion disposed apart from the cover panel; and
a component disposed under the metal layer.

18. The electronic device of claim 17,
further comprising a circuit board disposed between the metal layer and the component.

19. The electronic device of claim 17,
further comprising a first adhesive layer disposed between the metal layer and the cover panel.

20. The electronic device of claim 19, wherein
a distance between the first adhesive layer and the metal layer is 0.5 mm to 2.0 mm.
